(19) United States
(12) Patent Application Publication
(10) Pub. No.: US 2026/0122837 A1
(43) Pub. Date: Apr. 30, 2026

(54) COOLING SYSTEM

(71) Applicant: TOYOTA JIDOSHA KABUSHIKI KAISHA, Toyota-shi (JP)

(72) Inventor: Takuo WATANABE, Nagoya-shi (JP)

(73) Assignee: TOYOTA JIDOSHA KABUSHIKI KAISHA, Toyota-shi (JP)

(21) Appl. No.: 19/328,534

(22) Filed: Sep. 15, 2025

(30) Foreign Application Priority Data
Oct. 30, 2024 (JP) 2024-191137

(51) Int. Cl. H05K 7/20

(52) U.S. Cl. CPC H05K 7/20209

(57) ABSTRACT

A cooling system includes: a battery pack in which a battery module is housed; an intake duct and an exhaust duct that are connected to the battery pack; a blower disposed in a path extending from the intake duct to the exhaust duct; a predetermined sensor configured to acquire a detection value related to cooling of the battery pack; a storage unit configured to store relationship information related to the detection value from the sensor and a cooling capability of the battery pack; and a processing unit configured to determine a flooding level based on the relationship information and the detection value from the sensor.

### CROSS-REFERENCE TO RELATED APPLICATION

This application claims priority to Japanese Patent Application No. 2024-191137 filed on Oct. 30, 2024. The disclosure of the above-identified application, including the specification, drawings, and claims, is incorporated by reference herein in its entirety.

### BACKGROUND

### 1. Technical Field

The present disclosure relates to cooling systems.

### 2. Description of Related Art

Japanese Unexamined Patent Application Publication No. 2017-171176 (JP 2017-171176 A) discloses a cooling system that detects when a battery housed in a waterproof case becomes flooded with water.

### SUMMARY

In the related art, battery flooding is detected by determining a blockage state of a duct based on threshold values set for detection values such as fan rotational speed and blower power consumption that can be detected by sensors. However, while it is possible to determine whether the blockage is complete or partial, there is room for improvement in determining to what extent the blockage has progressed (i.e., the flooding level).

An object of the present disclosure is to provide a cooling system that enables determination of the flooding level with a simple sensor configuration.

A cooling system of claim 1 includes: a battery pack in which a battery module is housed; an intake duct and an exhaust duct that are connected to the battery pack; a blower disposed in a path extending from the intake duct to the exhaust duct; a predetermined sensor configured to acquire a detection value related to cooling of the battery pack; a storage unit configured to store relationship information related to the detection value from the sensor and a cooling capability of the battery pack; and a processing unit configured to determine a flooding level based on the relationship information and the detection value from the sensor. This configuration enables determination of the flooding level with a simple sensor configuration.

According to a cooling system of claim 2, in the cooling system of claim 1, the sensor is a pressure sensor installed on at least one of the battery pack, the intake duct, and the exhaust duct. The relationship information is a relationship map indicating a relationship between a rotational speed of the blower that is the detection value, and pressure loss related to the cooling capability. The processing unit is configured to determine the flooding level based on the relationship map and the detection value from the pressure sensor. The cooling system of claim 2 enables determination of the flooding level with a simple pressure sensor configuration,

According to a cooling system of claim 3, in the cooling system of claim 1, the sensor is a temperature sensor installed on the battery pack. The relationship information is a relationship map indicating a relationship between a rate of cooling performance degradation obtained based on a temperature of the battery pack that is the detection value, and a flooding level. The processing unit is configured to determine the flooding level based on the rate of cooling performance degradation calculated from the detection value from the temperature sensor using the relationship map. In the cooling system of claim 3, cooling performance degradation can be identified using a simple temperature sensor configuration, enabling determination of the flooding level.

According to a cooling system of claim 4, in the cooling system of claim 3, the temperature sensor includes a first temperature sensor configured to detect a first temperature that is an inlet temperature of the battery pack, and a second temperature sensor configured to detect a second temperature that is a battery temperature of the battery module. The processing unit is configured to: acquire, in advance, a first cooling amount before performance degradation by using the first temperature and the second temperature before the performance degradation; calculate, by using a temporal change in the second temperature detected during operation, a second cooling amount based on a temperature during the operation; calculate the rate of cooling performance degradation from the ratio of the second cooling amount to the first cooling amount; and determine the flooding level. In the cooling system of claim 4, cooling performance degradation can be identified using a simple temperature sensor configuration, enabling determination of the flooding level.

The technique of the present disclosure enables determination of a flooding level with a simple sensor configuration.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 shows the configuration of a cooling system according to a first embodiment;

FIG. 2 shows an example of a graph illustrating a relationship map;

FIG. 3 shows an example of a graph illustrating a relationship map;

FIG. 4 shows an example of how the rotational speed and the pressure vary with time during the determination of the flooding level;

FIG. 5 is a flowchart illustrating the processing flow of a processing device of the embodiment;

FIG. 6 shows a configuration example in which a pressure sensor is installed on an intake duct;

FIG. 7 shows the configuration of a cooling system according to a second embodiment;

FIG. 8 shows graphs illustrating an example in which battery-related detection values under flooded and non-flooded conditions are compared; and

FIG. 9 shows graphs illustrating an example in which the relationships among heat generation amount, cooling amount, and temperature before and after performance degradation are compared.

### DETAILED DESCRIPTION OF EMBODIMENTS

An overview of embodiments of the present disclosure will be described below. Conventionally, as described above, flooding of an in-vehicle battery has been detected by determining whether detection values exceed preset thresholds. However, such methods have difficulty in detecting the level of flooding. In a case where sensors for detecting the presence of water ingress is installed, it is necessary to add multiple components for flooding detection and to place water detection sensors at multiple locations, resulting in increased costs associated with sensor installation. Therefore, the embodiments of the present disclosure propose a cooling system that enables determination of the flooding level without using water detection sensors.

The embodiments of the present disclosure use a method in which the flooding level is determined using a relationship map related to the cooling capability of a battery pack, based on the pressure and temperature of the battery pack, namely the detection values related to cooling of the battery pack as detected by a predetermined sensor. The embodiments will be described below separately as a first embodiment and a second embodiment.

### First Embodiment

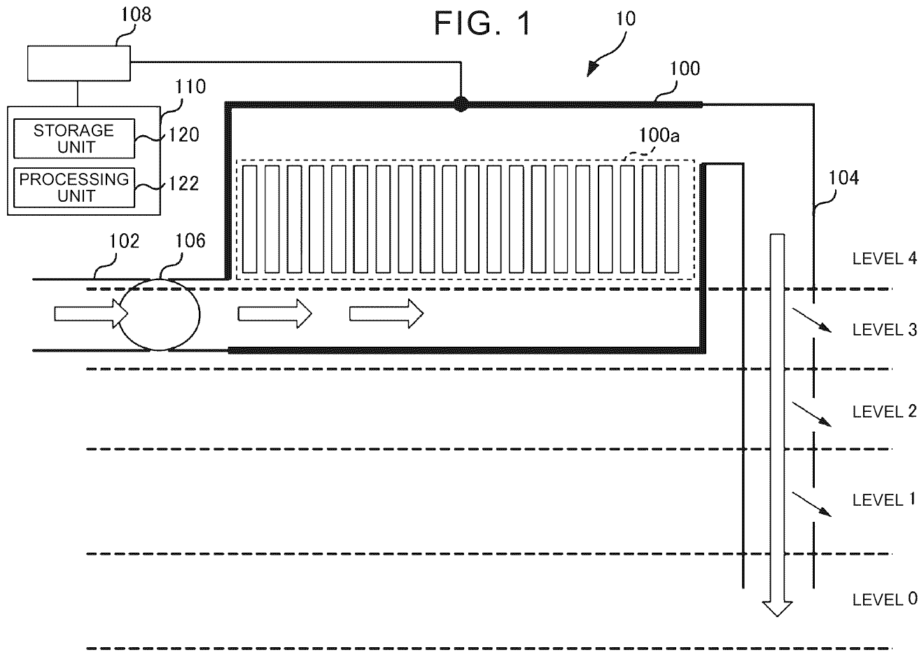

FIG. 1 shows the configuration of a cooling system 10 according to a first embodiment. As shown in FIG. 1, a cooling system 10 includes: a battery pack 100 in which a battery module 100a is housed; an intake duct 102 and an exhaust duct 104 that are connected to the battery pack 100; a blower 106; a pressure sensor 108; and a processing device 110. The processing device 110 is connected to the pressure sensor 108 and functionally includes a storage unit 120 and a processing unit 122.

The processing device 110 is implemented, as a hardware configuration, by a computer that includes a central processing unit (CPU), a read-only memory (ROM) storing, for example, programs for implementing various processes, a random access memory (RAM) for temporarily storing data, a memory serving as storage means, and a network interface.

As a premise, in the cooling system 10 that is an in-vehicle cooling mechanism, cool air is blown from the vehicle cabin to the battery pack 100 to cool the battery module 100a itself. The cooling system 10 includes the intake duct 102 and the blower 106 for supplying the airflow. In the exhaust duct 104 (or the intake duct 102), the airflow through air holes changes due to water ingress. The change in airflow also causes a change in pressure loss. In the present embodiment, the flooding level is determined based on such a principle.

The air flow through the air holes of the exhaust duct 104 changes depending on the flooding level. In the present embodiment, flooding levels are defined in stages from Level 0 to Level 4. The example of FIG. 1 shows how the flooding levels, defined from Level 0 to Level 4, correspond to the air holes of the exhaust duct 104.

The storage unit 120 stores, as relationship information, a relationship map indicating characteristics of the relationship between the rotational speed of the blower 106 and the pressure loss associated with cooling capability. Threshold pressure values corresponding to the rotational speeds for each predefined flooding level are stored in the relationship map.

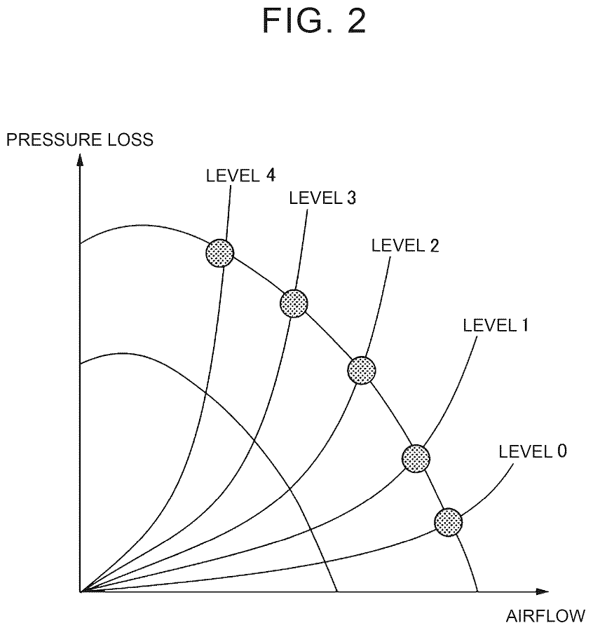

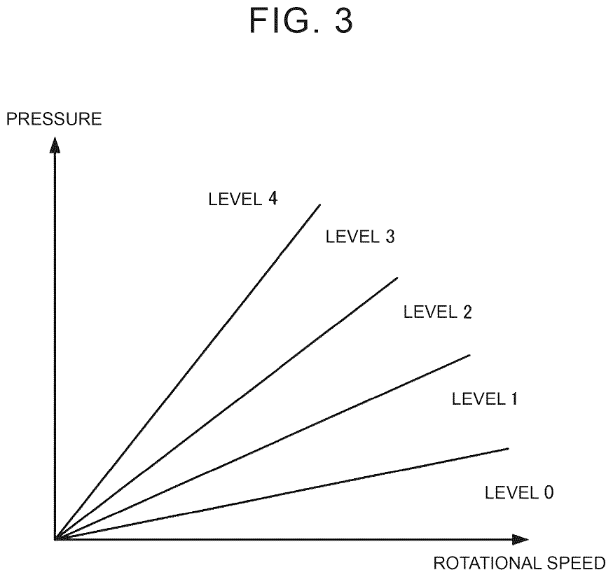

FIGS. 2 and 3 are examples of graphs showing the relationship map. The graph in FIG. 2 illustrates the relationship of flooding level with respect to pressure loss and airflow (PQ characteristic), where the vertical axis represents pressure loss, and the horizontal axis represents airflow. Pressure loss curves for Levels 0 to 4 are shown as changes in the characteristics of the relationship map. In principle, the higher the flooding level, the higher the pressure generated when operating at the same rotational speed. The graph in FIG. 3 illustrates a relationship map between the rotational speed of the blower 106 and the pressure. This relationship map corresponds to that of FIG. 2, with airflow replaced with rotational speed and pressure loss replaced with pressure. The graph in FIG. 3 illustrates the relationship of flooding level with respect to pressure and rotational speed, where the vertical axis represents pressure, and the horizontal axis represents the rotational speed of the blower 106. FIG. 3 shows that pressure and rotational speed exhibit a proportional relationship as the flooding level changes.

When the rotational speed of the blower 106 is greater than or equal to a certain value, the processing unit 122 determines the flooding level based on the relationship map and the detection value from the pressure sensor 108. In the first embodiment, the detection values are the rotational speed of the blower 106 and the pressure.

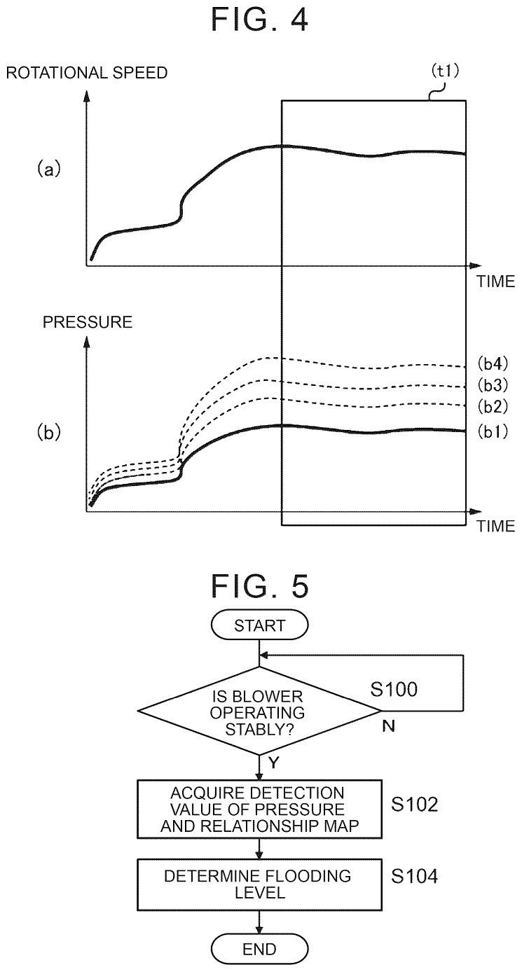

FIG. 4 shows an example of how the rotational speed and the pressure vary with time during the determination of the flooding level. In FIG. 4, part (a) shows how the rotational speed varies with time, and part (b) shows how the pressure varies with time. While the rotational speed becomes constant after stable operation is achieved, the pressure varies depending on the flooding level. In the present embodiment, the determination is performed within a period (t1) during which the rotational speed is stable. As shown in part (b), pressure increases as the flooding level rises. Accordingly, the flooding level can be determined based on threshold values predefined in the relationship map for each flooding level and the detection value of the pressure. The continuous line (b1) indicates the pressure in the baseline state corresponding to Level 0, while the dashed lines (b2) to (b4) indicate the pressures in the states corresponding to Levels 1 to 3, respectively. The values corresponding to the pressures indicated by the dashed lines are used as thresholds for the respective flooding levels.

### Control Flow

FIG. 5 is a flowchart illustrating the processing flow of the processing device 110 of the present embodiment. The following process may be periodically performed after the blower 106 starts operating.

In step S100, the processing unit 122 determines whether the rotational speed acquired from the blower 106 indicates stable operation. Stable operation may be determined based on whether the rotational speed has been greater than or equal to a certain value for a predetermined period of time. When stable operation is determined to have been achieved, the process proceeds to step S102. Otherwise, step S100 is repeated.

In step S102, the processing unit 122 acquires a detection value of the pressure from the pressure sensor 108 and the relationship map from the storage unit 120.

In step S104, the flooding level is determined based on the relationship map and the detection value from the pressure sensor 108.

### Modifications of First Embodiment

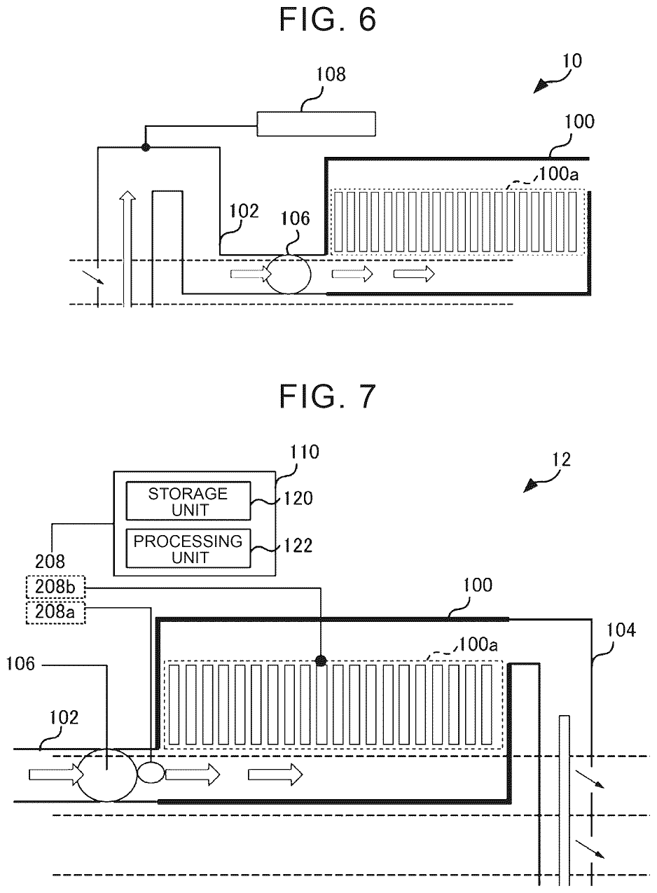

The pressure sensor 108 is not necessarily installed on the battery pack 100, and may be installed on the upstream intake duct 102 or the downstream exhaust duct 104. FIG. 6 shows a configuration example in which the pressure sensor 108 is installed on the intake duct 102. For convenience, FIG. 6 schematically illustrates only the components necessary for the description. A similar configuration can be used when the pressure sensor 108 is installed on the exhaust duct 104.

As described above, in the first embodiment, the use of a pressure-related relationship map enables the flooding level to be determined with a simple pressure sensor configuration.

### Second Embodiment

The first embodiment uses a pressure-related relationship map, whereas a second embodiment uses a temperature-related relationship map. The principle of the second embodiment will be described. As described in the first embodiment, the higher the flooding level, the higher the pressure generated when operating at the same rotational speed. As the pressure increases, the airflow decreases. A decrease in airflow leads to a reduction in cooling performance. As the cooling performance decreases, the temperature rises. Based on this principle, the second embodiment uses a temperature sensor.

FIG. 7 shows the configuration of a cooling system 12 according to the second embodiment. As shown in FIG. 7, the cooling system 12 includes: the battery pack 100 in which the battery module 100a is housed; the intake duct 102 and the exhaust duct 104 that are connected to the battery pack 100; the blower 106; a temperature sensor 208; and the processing device 110. The processing device 110 is connected to the temperature sensor 208 and functionally includes the storage unit 120 and the processing unit 122. The temperature sensor 208 includes a first temperature sensor 208a that detects a first temperature, and a second temperature sensor 208b that detects a second temperature. The first temperature is the inlet temperature of the battery pack 100 (intake temperature), and the second temperature is the battery temperature of the battery module 100a. In the second embodiment, the detection values are the first temperature and the second temperature. In addition, the battery load of the battery pack 100 is acquired by an optional sensor (not shown).

The storage unit 120 stores, as relationship information, a relationship map indicating a relationship between the flooding level and a rate of cooling performance degradation. The rate of cooling performance degradation is based on a first cooling amount before performance degradation and a second cooling amount obtained based on the temperature during operation. A formula for deriving the first cooling amount and a formula for deriving the second cooling amount are also stored therein.

The processing unit 122 acquires in advance the first cooling amount before performance degradation. The first cooling amount is calculated in advance using the first temperature and the second temperature. The first cooling amount thus acquired is stored in the storage unit 120.

A method for calculating the first cooling amount will now be described. For the calculation, an internal resistance RI, a heat capacity C, a cooling coefficient Kf, and a blower qN characteristic are acquired in advance. The blower qN characteristic is a value proportional to the airflow and the rotational speed. In addition, a first temperature Tc and a second temperature Tb before performance degradation are also acquired.

First, the cooling amount (QC) is calculated using Equation (1) regarding the relationship between the cooling coefficient Kf and the airflow q.

$$QC = Kf \cdot q ( Tb - Tc ) \qquad ( 1 )$$

The cooling coefficient Kf is defined as Kf=RI\hat{ }2/q (Tb−Tc).
The first cooling amount QC_{T(Kf)} before performance degradation is calculated as a total over a predetermined period from T1 to T2 using Equation (2) below.

$$Q {C}_{T ( Kf )} = Σ QC = Σ ( Kf / q ( Tb - Tc ) ) \qquad ( 2 )$$

The processing unit 122 calculates the second cooling amount based on the temperature during operation, and calculates the rate of cooling performance degradation from the ratio of the second cooling amount to the first cooling amount. The processing unit 122 determines the flooding level by referring to the flooding level in the relationship map corresponding to the calculated rate.

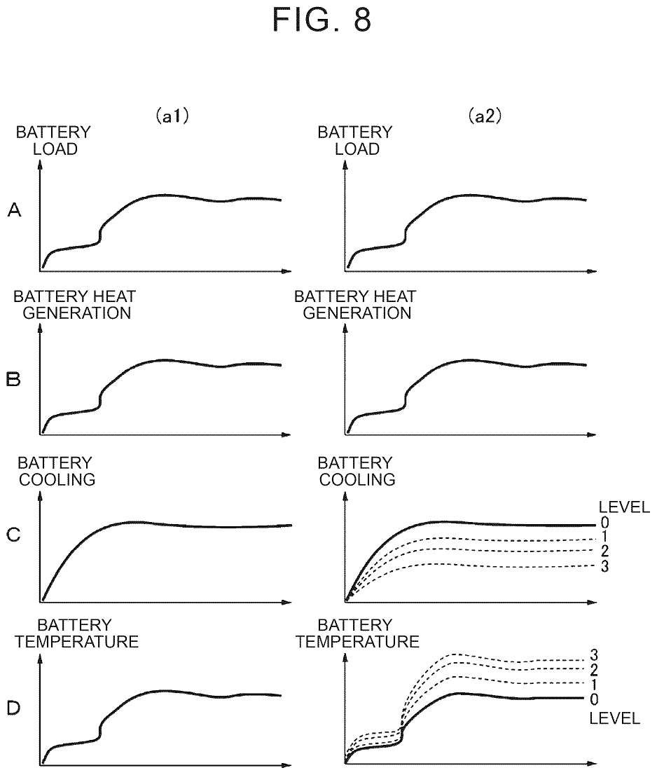

FIG. 8 shows graphs illustrating an example in which battery-related detection values under flooded and non-flooded conditions are compared. In these graphs, the vertical axis represents battery load (A), battery heat generation (B), battery cooling (C), and battery temperature (D), respectively, and the horizontal axis represents time. Part (a1) corresponds to the non-flooded condition, and part (a2) corresponds to the flooded condition. Graph C of part (a2) shows battery cooling under the flooded condition, illustrating that the cooling amount decreases as the flooding level increases. Graph D of part (a2) shows battery temperature under the flooded condition, illustrating that as the flooding level increases, the cooling amount decreases, leading to a rise in temperature.

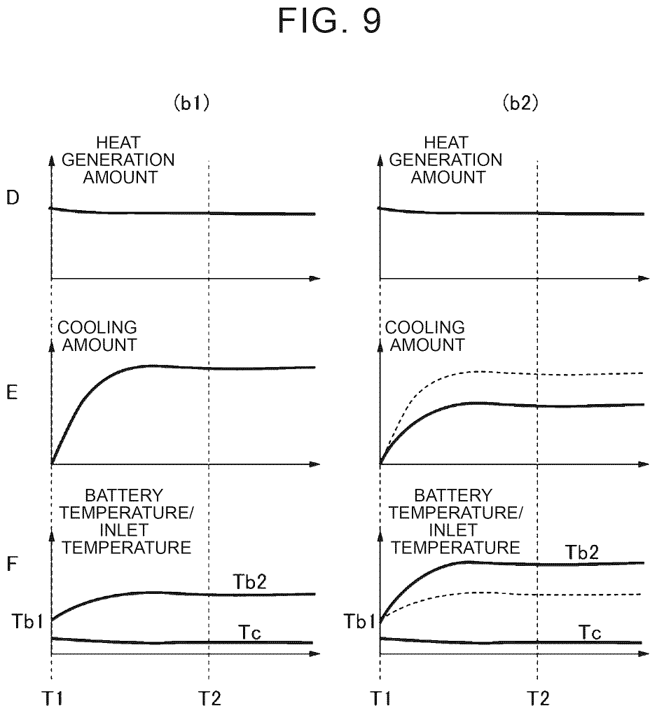

FIG. 9 shows graphs illustrating an example in which the relationships among heat generation amount, cooling amount, and temperature before and after performance degradation are compared. Part (b1) corresponds to before performance degradation, and part (b2) corresponds to after performance degradation. In these graphs, the vertical axis represents heat generation amount (E), cooling amount (F), battery temperature/inlet temperature (G), respectively, and the horizontal axis represents time. In the example, time points T1, T2 are shown in the graphs. The cooling amount decreases after performance degradation compared to before performance degradation. Regarding temperature, it can be seen that the inlet temperature Tc does not decrease, whereas the battery temperature Tb decreases.

A method for calculating the second cooling amount will be described. The second cooling amount is calculated based on the rise in battery temperature. The increase in Tb from T1 to T2 is defined as ΔT=Tb2−Tb1.

The heat generation amount QH is calculated by QH=R·I\hat{ }2. The heat generation amount QH_{T} from T1 to T2 is calculated using Equation (3) below.

$$Q {H}_{T} = Σ QH = Σ ( R \cdot {I}^{⋀} 2 ) \qquad ( 3 )$$

The temperature rise of the battery is calculated by ΔT=1/C(QH_{T}−QC_{T}). By rearranging the equation, the second cooling amount QC_{T(ΔT)} can be expressed as QC_{T(ΔT)}=QH_{T}−ΔT·C.

The processing unit 122 calculates the rate of cooling performance degradation by Equation (4) below using the first cooling amount QC_{T(Kf)} and the second cooling amount QC_{T(ΔT)}.

$$Rate of cooling performance degradation = {QC}_{T ( Δ T )} / {QC}_{T ( Kf )} \qquad ( 4 )$$

Table 1 shows an example of a relationship map indicating the relationship between the rate of cooling performance degradation and the flooding level.

TABLE 1

Performance Degradation (%)

| | | Up | Up | Up | Up | Up |
|---|---|---|---|---|---|---|
| | 100 | to 90 | to 80 | to 70 | to 60 | to 50 |
| Flooding | 0 | 0 | 1 | 2 | 3 | 4 |
| Level | | | | | | |

The flow of the second embodiment may be implemented by replacing the flow of the first embodiment shown in FIG. 5. In step S100, the processing unit 122 acquires the first cooling amount before performance degradation. In step S102, the processing unit 122 calculates the second cooling amount based on the temperature during operation, and calculates the rate of cooling performance degradation from the ratio of the second cooling amount to the first cooling amount. In step S104, the processing unit 122 determines the flooding level by referring to the flooding level in the relationship map corresponding to the calculated rate.

As described above, in the second embodiment, the use of a temperature-related relationship map enables the flooding level to be determined with a simple pressure sensor configuration.

In the above embodiments, the various processes performed by the CPU by reading and executing software (programs) may be performed by various types of processors other than the CPU. Examples of such processors include: programmable logic devices (PLDs) that allow circuit configurations to be modified after manufacturing, such as field-programmable gate arrays (FPGAs); and dedicated electrical circuits that are processors having circuit configurations specially designed to perform specific processes, such as graphics processing units (GPUs) and application-specific integrated circuits (ASICs). The processes described above may be performed by one of these various types of processors, or may be performed by a combination of two or more processors of the same or different types (for example, a plurality of FPGAs, or a combination of a CPU and an FPGA). The hardware configuration of these various types of processors is, more specifically, an electrical circuit formed by combining circuit elements such as semiconductor elements.

In the above embodiment, the information processing program has been described as being stored (installed) in advance on a computer-readable non-transitory recording medium. For example, the information processing program is stored in advance in a ROM or storage. However, the present disclosure is not limited to this, and each program may be provided in a form recorded on a non-transitory recording medium such as a compact disc read-only memory (CD-ROM), a digital versatile disc read-only memory (DVD-ROM), or a Universal Serial Bus (USB) memory. The information processing program may be provided in a form that is downloaded from an external device via a network.

The processing flow described in the above embodiment is merely an example, and steps may be omitted, added, or rearranged as appropriate without departing from the spirit and scope of the disclosure.

What is claimed is:

1. A cooling system comprising:
a battery pack in which a battery module is housed;
an intake duct and an exhaust duct that are connected to the battery pack;
a blower disposed in a path extending from the intake duct to the exhaust duct;
a predetermined sensor configured to acquire a detection value related to cooling of the battery pack;
a storage unit configured to store relationship information related to the detection value from the sensor and a cooling capability of the battery pack; and
a processing unit configured to determine a flooding level based on the relationship information and the detection value from the sensor.

2. The cooling system according to claim 1, wherein:
the sensor is a pressure sensor installed on at least one of the battery pack, the intake duct, and the exhaust duct;
the relationship information is a relationship map indicating a relationship between a rotational speed of the blower that is the detection value, and pressure loss related to the cooling capability; and
the processing unit is configured to determine the flooding level based on the relationship map and the detection value from the pressure sensor.

3. The cooling system according to claim 1, wherein:
the sensor is a temperature sensor installed on the battery pack;
the relationship information is a relationship map indicating a relationship between a rate of cooling performance degradation obtained based on a temperature of the battery pack that is the detection value, and a flooding level; and
the processing unit is configured to determine the flooding level based on the rate of cooling performance degradation calculated from the detection value from the temperature sensor using the relationship map.

4. The cooling system according to claim 3, wherein:
the temperature sensor includes a first temperature sensor configured to detect a first temperature that is an inlet temperature of the battery pack, and a second temperature sensor configured to detect a second temperature that is a battery temperature of the battery module; and
the processing unit is configured to: acquire, in advance, a first cooling amount before performance degradation by using the first temperature and the second temperature before the performance degradation; calculate, by using a temporal change in the second temperature detected during operation, a second cooling amount based on a temperature during the operation; calculate the rate of cooling performance degradation from a ratio of the second cooling amount to the first cooling amount; and determine the flooding level.
